(19) United States
(12) Patent Application Publication
(10) Pub. No.: US 2026/0075717 A1
(43) Pub. Date: Mar. 12, 2026

(54) INFORMATION PROCESSING APPARATUS

(71) Applicant: CXMT Corporation, Hefei (CN)

(72) Inventors: Yuan FANG, Hefei (CN); Yanwu WANG, Hefei (CN)

(21) Appl. No.: 19/394,909

(22) Filed: Nov. 20, 2025

Related U.S. Application Data
(63) Continuation of application No. PCT/CN2023/126685, filed on Oct. 26, 2023.

(30) Foreign Application Priority Data
Jun. 16, 2023 (CN) 202310728159.4

(51) Int. Cl. H05K 1/18; G06F 1/18

(52) U.S. Cl. CPC H05K 1/18; G06F 1/184; H05K 2201/10159

(57) ABSTRACT

Embodiments of the present disclosure relate to an information processing apparatus. The information processing apparatus includes: a main board, provided with a first surface, where the first surface is provided with a central processing unit electrically connected to the main board; a compression attached memory module, located on one side of the first surface, where at least one surface of the compression attached memory module is provided with a plurality of chips; and an external connecting structure, located on one side of the first surface, and configured to: electrically connect the compression attached memory module and the central processing unit, where the central processing unit is configured to: read data from and write data to each chip at least via the external connecting structure.

### CROSS-REFERENCE TO RELATED APPLICATIONS

The present application is a continuation application of Internation Patent Application No. PCT/CN2023/126685, filed on Oct. 26, 2023, which claims priority to Chinese Patent Application No. 202310728159.4, filed on Jun. 16, 2023, and entitled “INFORMATION PROCESSING APPARATUS”, which is incorporated herein by reference in its entirety.

### TECHNICAL FIELD

Embodiments of the present disclosure relate to the technical field of semiconductors, and in particular, to an information processing apparatus.

### BACKGROUND

A compression attached memory module (compression attached memory module, CAMM) is a new type of memory module. The CAMM connects a plurality of chips, fixes the plurality of chips on a main board, and electrically connects the main board and the chips. A central processing unit electrically connected to the main board can write data to the chips or read data from the chips. Compared with a conventional memory module, the compression attached memory module features a thinner design and superior heat dissipation.

Signal transmission between the chips and the central processing unit is usually achieved through signal lines located in the main board. However, as the number of chips connected to the CAMM increases, the number of signal lines in the main board increases, which not only increases the thickness of the main board and slows down the heat dissipation of the main board, but also increases the trace density of the signal lines in the main board, resulting in serious crosstalk between the signal lines and causing signal distortion.

### SUMMARY

Embodiments of the present disclosure provide an information processing apparatus.

The embodiments of the present disclosure provide an information processing apparatus. The information processing apparatus includes: a main board, provided with a first surface, where the first surface is provided with a central processing unit electrically connected to the main board; a compression attached memory module, located on one side of the first surface, where at least one surface of the compression attached memory module is provided with a plurality of chips; and an external connecting structure, located on one side of the first surface, and configured to: electrically connect the compression attached memory module and the central processing unit, where the central processing unit is configured to: read data from and write data to each of the plurality of chips at least via the external connecting structure.

### BRIEF DESCRIPTION OF DRAWINGS

One or more embodiments are exemplarily illustrated with reference to figures in the corresponding drawings, and these exemplary illustrations are not to be construed as limiting the embodiments. Unless expressly stated otherwise, the figures in the drawings do not constitute a limitation of scale. To more clearly illustrate the technical solutions in the embodiments of the present disclosure or conventional technology, a brief introduction to the drawings required to be used in the embodiments is given hereinafter. It is evident that the drawings described hereinafter are merely some embodiments of the present disclosure. For those of ordinary skill in the art, other drawings may be further obtained based on these drawings without creative effort.

FIG. 1 is a schematic cross-sectional diagram of a first information processing apparatus according to an embodiment of the present disclosure;

FIG. 2 is a schematic cross-sectional diagram of a second information processing apparatus according to an embodiment of the present disclosure;

FIG. 3 is a three-dimensional schematic structural diagram of an information processing apparatus according to an embodiment of the present disclosure;

FIG. 4 is a schematic cross-sectional diagram of a third information processing apparatus according to an embodiment of the present disclosure;

FIG. 5 is a schematic cross-sectional diagram of a fourth information processing apparatus according to an embodiment of the present disclosure;

FIG. 6 is a schematic cross-sectional diagram of a fifth information processing apparatus according to an embodiment of the present disclosure;

FIG. 7 is a schematic cross-sectional diagram of a sixth information processing apparatus according to an embodiment of the present disclosure;

FIG. 8 is a schematic cross-sectional diagram of a seventh information processing apparatus according to an embodiment of the present disclosure;

FIG. 9 is a schematic cross-sectional diagram of an eighth information processing apparatus according to an embodiment of the present disclosure;

FIG. 10 is a schematic cross-sectional diagram of a ninth information processing apparatus according to an embodiment of the present disclosure;

FIG. 11 is a schematic cross-sectional diagram of a tenth information processing apparatus according to an embodiment of the present disclosure; and

FIG. 12 is a three-dimensional schematic structural diagram of another information processing apparatus according to an embodiment of the present disclosure.

### DESCRIPTION OF EMBODIMENTS

As can be learned from the background, the heat dissipation capability of a main board in a current information processing apparatus is relatively poor. It is found by analysis that, currently, one of the reasons for the poor heat dissipation capability of the main board is that the main board is provided with a large number of signal lines configured to electrically connect the central processing unit and the compression attached memory module. As the number of chips connected to the compression attached memory module increases, the number of signal lines in the main board increases, leading to an increase in the thickness of the main board and a significant decrease in the heat dissipation capability of the main board.

Embodiments of the present disclosure provide an information processing apparatus. An external connecting structure is arranged on one side of a first surface of a main board and is configured to electrically connect a compression attached memory module and a central processing unit. That is, the external connecting structure is routed from the outside of the main board to connect the compression attached memory module and the central processing unit. In this way, the number of signal lines in the main board configured to electrically connect the central processing unit and the compression attached memory module can be reduced, and even the arrangement of the signal lines in the main board can be eliminated, thereby significantly reducing the thickness of the main board and significantly increasing the heat dissipation capability of the main board.

The embodiments of the present disclosure will be described in detail below with reference to the drawings. However, those of ordinary skill in the art can understand that, in the embodiments of the present disclosure, numerous technical details are set forth to enable readers to better understand the present disclosure. However, the technical solutions claimed by the present disclosure can also be implemented even without these technical details and the various changes and modifications based on the following embodiments.

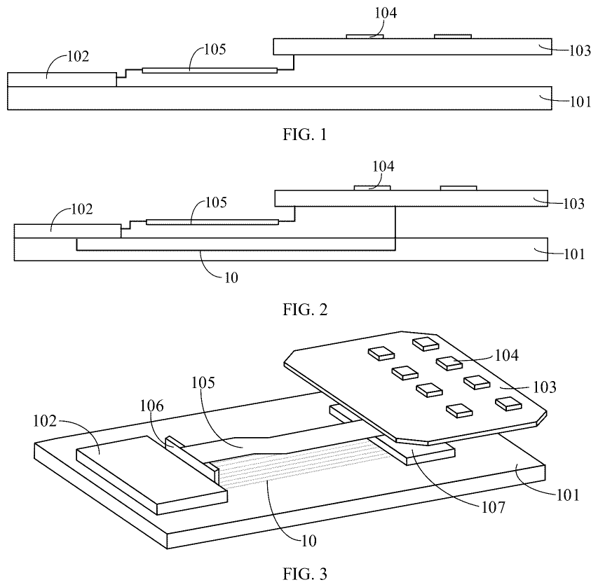

FIG. 1 is a schematic cross-sectional diagram of a first information processing apparatus according to an embodiment of the present disclosure.

Referring to FIGS. 1 to 3, the information processing apparatus includes: a main board 101, provided with a first surface, the first surface being provided with a central processing unit 102 electrically connected to the main board 101. The information processing apparatus further includes: a compression attached memory module 103, located on one side of the first surface. At least one surface of the compression attached memory module 103 is provided with a plurality of chips 104. The information processing apparatus further includes: an external connecting structure 105, located on one side of the first surface, and configured to: electrically connect the compression attached memory module 103 and the central processing unit 102. The central processing unit 102 is configured to: read data from and write data to each chip 104 at least via the external connecting structure 105.

The central processing unit 102 is referred to as CPU. As the computing and control core of a computer system, the central processing unit 102 is the ultimate execution unit for information processing and program operation.

The main board 101 is also referred to as a motherboard. The main board 101 may be used as a carrier of the central processing unit 102 and the compression attached memory module 103, and achieve the electrical connection between the central processing unit 102 and the compression attached memory module 103. In some embodiments, the main board 101 may be a system board, a logic board, or any other printed circuit board.

The compression attached memory module 103, i.e., “compression attached memory module” (CAMM), is a new form different from a conventional SO-DIMM laptop memory. The structure of the compression attached memory module includes: a PCB circuit board and a chip 104 that can be mounted on both sides.

When writing data to the chip 104, the central processing unit 102 may transmit address information through an address line, then transmit a memory write command through a control line to select the chip 104, and write data to the selected chip 104 through the external connecting structure 105. When reading data from the chip 104, the central processing unit 102 transmits address information through an address line, and then transmits a memory read command through a control line to select the chip 104. The selected chip 104 transmits the data in the chip 104 to the central processing unit 102 through the external connecting structure 105.

In some embodiments, the chip 104 may include any one of dynamic random access memory (dynamic random access memory, DRAM), static random-access memory (static random-access memory, SRAM), or synchronous dynamic random-access memory (synchronous dynamic random-access memory, SDRAM).

In a specific example, the chip 104 may be a DRAM, and may specifically be some variants of synchronous DRAM, for example, DDR3 (DDR version 3), DDR4 (DDR version 4), DDR5 (DDR version 5), LPDDR3 (low power DDR version 3), LPDDR4 (LPDDR version 4), LPDDR5 (LPDDR version 5), or another memory technology, or a combination of memory technologies.

The external connecting structure 105 is located on one side of the first surface of the main board 101, that is, the external connecting structure 105 is arranged outside the main board 101 to achieve the electrical connection between the central processing unit 102 and the compression attached memory module 103. Since the chip 104 is electrically connected to the compression attached memory module 103, the central processing unit 102 can read data from and write data to the chip 104 through the external connecting structure 105 and the compression attached memory module 103.

FIG. 2 is a schematic cross-sectional diagram of a second information processing apparatus according to an embodiment of the present disclosure, and FIG. 3 is a three-dimensional schematic structural diagram of an information processing apparatus according to an embodiment of the present disclosure.

Referring to FIGS. 2 and 3, in some embodiments, the main board 101 is provided with a plurality of signal lines 10, each signal line 10 electrically connects the central processing unit 102 and the compression attached memory module 103, and the central processing unit 102 is configured to: read data from and write data to each chip 104 via the signal line 10 and the external connecting structure 105. That is, both the external connecting structure 105 and the signal line 10 can achieve signal transmission between the central processing unit 102 and the chip 104. The signal line 10 is located inside the main board 101, and the external connecting structure 105 is located outside the main board 101, such that the number of signal lines 10 in the main board 101 can be significantly reduced. In one aspect, the volume occupied by the signal lines 10 inside the main board 101 can be reduced, and the thickness of the main board 101 can be reduced, which is beneficial to enhancing the heat dissipation of the main board 101. In another aspect, the trace density of the signal lines 10 in the main board 101 is significantly reduced, thereby avoiding the crosstalk between the signals transmitted in different signal lines 10 due to the excessively high trace density of the signal lines 10, and avoiding the distortion of the signals transmitted in the signal lines 10.

By using the external connecting structure 105 together with the signal lines 10 to achieve the signal transmission between the central processing unit 102 and the chip 104, the flexibility of routing of the external connecting structure 105 and the signal lines 10 can be enhanced. This can not only avoid the problem of excessive trace density of the external connecting structure 105 but also avoid the problem of excessive trace density of the signal lines 10, thereby significantly reducing the risk of signal distortion caused by the excessively high trace density.

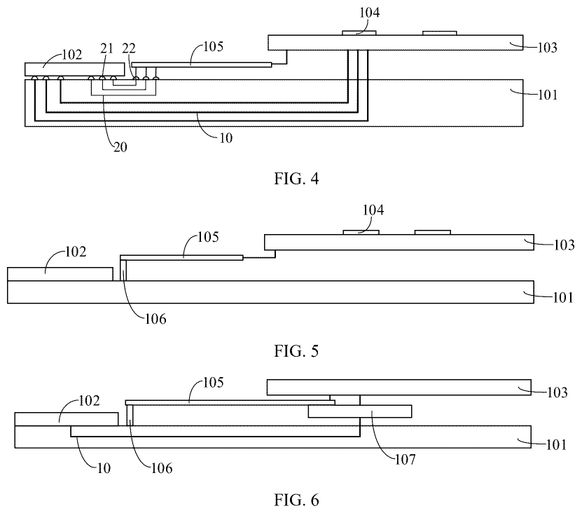

Referring to FIG. 4, in some embodiments, the main board 101 is further provided with a plurality of signal lines 10, and the information processing apparatus further includes: first pins 21, located on the first surface. The central processing unit 102 is electrically connected to the first pins 21 to achieve the electrical connection with the main board 101. The signal lines 10 are electrically connected to a portion of the first pins 21, thereby electrically connecting the central processing unit 102 and the compression attached memory module 103.

The information processing apparatus further includes: second pins 22, located on the first surface. The second pins 22 are electrically connected to the remaining portion of the first pins 21, and the second pins 22 are electrically connected to the external connecting structure 105 to achieve the electrical connection between the central processing unit 102 and the external connecting structure 105. In some embodiments, the main board 101 further includes first wires 20, the first wires 20 being configured to electrically connect the first pins 21 and the second pins 22, such that the second pins 22 can be electrically connected to the central processing unit 102, and thus the external connecting structure 105 electrically connected to the second pins 22 can be electrically connected to the central processing unit 102.

In some embodiments, the second pins 22 are located on the first surface between the central processing unit 102 and the compression attached memory module 103, and are arranged adjacent to the first pins 21. In this way, the length of the first wire 20 in the main board 101 is relatively short, reducing the transmission loss of the signals transmitted in the first wire 20. Moreover, since the length of the first wire 20 is relatively short, the loss of the signals transmitted in the first wire 20 is relatively small. Therefore, the diameter of the first wire 20 may be set to be relatively small, thereby reducing the volume occupied by the first wire 20 in the main board 101, and avoiding an increase in the thickness of the main board 101 due to the arrangement of the first wire 20.

In some embodiments, the diameter of the first wire 20 may be smaller than the diameter of the signal line 10. In this way, it can be ensured that the arrangement of the first wire 20 does not cause a further increase in the thickness of the main board 101.

It can be understood that, in some embodiments, the signal line 10 may not be arranged in the main board 101, such that signals are transmitted between the chip 104 and the central processing unit 102 only through the external connecting structure 105. In this way, the thickness of the main board 101 can be significantly reduced, further enhancing the heat dissipation of the main board 101.

In some embodiments, the signals are transmitted between the chip 104 and the central processing unit 102 only through the external connecting structure 105, and the information processing apparatus further includes: first pins, located on the first surface. The central processing unit 102 is electrically connected to the first pins to achieve the electrical connection with the main board 101.

The information processing apparatus further includes: second pins, located on the first surface. The second pins are electrically connected to the first pins, and the second pins are electrically connected to the external connecting structure 105 to achieve the electrical connection between the central processing unit 102 and the external connecting structure 105. In some embodiments, the main board 101 further includes first wires, the first wires being configured to electrically connect the first pins and the second pins.

In some embodiments, the first pin may be any one of a gold finger or a ball grid array, and the second pin may be any one of a gold finger or a ball grid array.

The gold finger is a structure composed of a plurality of golden conductive contact pieces, and is referred to as a gold finger because the surface thereof is plated with gold and the conductive contact pieces are arranged in a finger-like shape.

The ball grid array consists of spherical contacts formed in an array on the first surface of the main board 101. In some embodiments, the spherical contacts may be solder balls arranged in an array.

Both the gold finger and the ball grid array can be formed on the first surface in a manner well known to those skilled in the art and in electrical contact with the central processing unit 102.

In some embodiments, the first wire 20 may be formed in the main board 101 by electroplating, and the embodiments of the present disclosure do not limit the specific wiring method and shape of the first wire 20 in the main board 101, as long as the first wire 20 can electrically connect the first pin 21 and the second pin 22. The material of the first wire 20 may be a metal material, such as at least one of copper, tungsten, nickel, silver, or other conductive materials well known to those skilled in the art.

Referring to FIGS. 1 to 3, in some embodiments, the external connecting structure 105 is located on one side of the compression attached memory module 103 facing the central processing unit 102. The central processing unit 102 and the compression attached memory module 103 are both located on the first surface, and the central processing unit 102 and the compression attached memory module 103 are oppositely arranged. The external connecting structure 105 may be located between the central processing unit 102 and the compression attached memory module 103. The external connecting structure 105 is located on one side of the compression attached memory module 103 facing the central processing unit 102, that is, the external connecting structure 105 is directly opposite to the compression attached memory module 103, and the height of the external connecting structure 105 relative to the first surface is not higher than the height of the compression attached memory module 103 relative to the first surface. That is, the external connecting structure 105 can be arranged by using the free space between the compression attached memory module 103 and the central processing unit 102, and since the height of the external connecting structure 105 is not higher than the height of the compression attached memory module 103, the external connecting structure 105 does not occupy excessive additional volume, thereby preventing the problem that the thickness of the information processing apparatus cannot be further reduced due to the excessive thickness of the external connecting structure 105.

In some embodiments, the height of the compression attached memory module relative to the main board 101 is greater than the height of the central processing unit 102 relative to the main board 101. In other words, the height of the surface of the compression attached memory module 103 distal to the main board 101 relative to the first surface is greater than the height of the surface of the central processing unit 102 distal to the main board 101 relative to the first surface.

Referring to FIG. 5, in some embodiments, the information processing apparatus further includes: a central processing unit connector 106. The central processing unit connector 106 is located on the first surface, and the central processing unit connector 106 is configured to electrically connect the external connecting structure 105 and the central processing unit 102. The central processing unit connector 106 is located between the central processing unit 102 and the compression attached memory module 103, and is arranged adjacent to the central processing unit 102. In this way, the distance between the central processing unit connector 106 and the central processing unit 102 is short, which is beneficial to enhancing the electrical transmission performance between the central processing unit 102 and the external connecting structure 105.

In some embodiments, the bottom surface of the central processing unit connector 106 facing the first surface is electrically connected to the central processing unit 102, and the top surface of the central processing unit connector 106 distal to the first surface is electrically connected to the external connecting structure 105. The bottom surface of the central processing unit connector 106 is in electrical contact with the gold finger or the ball grid array located on the first surface, the top surface of the central processing unit connector 106 is provided with a ball grid array or a press-type connector, and the central processing unit connector 106 is in electrical contact with the external connecting structure 105 through any one of the ball grid array, the press-type connector, or a silicon interposer located on the top surface.

One end of the external connecting structure 105 is electrically connected to the central processing unit 102, and the other end is electrically connected to the compression attached memory module 103. That is, the external connecting structure 105 extends in a direction in which the central processing unit 102 points to the compression attached memory module 103. Since the height of the compression attached memory module 103 relative to the first surface is higher than the height of the central processing unit 102 relative to the first surface, there is a large height difference between the compression attached memory module 103 and the central processing unit 102. This may cause the heights of the two ends of the external connecting structure 105 to be inconsistent, resulting in a problem that the external connecting structure 105 is inclined relative to the first surface, thereby causing a large space occupied by the external connecting structure 105.

Based on the above considerations, in some embodiments, the height of the central processing unit connector 106 relative to the main board 101 is greater than the height of the central processing unit 102 relative to the main board 101. In other words, the height of the surface of the central processing unit connector 106 distal to the main board 101 relative to the main board 101 is greater than the height of the surface of the central processing unit 102 distal to the main board 101 relative to the main board 101. In this way, the height difference between the central processing unit connector 106 and the compression attached memory module 103 is smaller than the height difference between the central processing unit 102 and the compression attached memory module 103. Since the external connecting structure 105 is electrically connected to the central processing unit connector 106, compared to being directly connected to the central processing unit 102, the height difference between the external connecting structure 105 and the compression attached memory module 103 is relatively small, such that the inclination of the external connecting structure 105 relative to the first surface is not excessively large, thereby alleviating the problem that the external connecting structure 105 occupies a relatively large space.

Referring to FIG. 6, in some embodiments, the bottom surface of the central processing unit connector 106 facing the first surface is electrically connected to the central processing unit 102, and the top surface of the central processing unit connector 106 distal to the first surface is electrically connected to the external connecting structure 105. In this way, the height of the external connecting structure 105 is higher than the height of the central processing unit connector 106, which can minimize the height difference between the external connecting structure 105 and the compression attached memory module 103. Since the two ends of the external connecting structure 105 are electrically connected to the central processing unit connector 106 and the compression attached memory module 103, respectively, reducing the height difference between the external connecting structure 105 and the compression attached memory module 103 results in a relatively small height difference between the two ends of the external connecting structure 105, or even 0. Moreover, the external connecting structure 105 can be placed horizontally or nearly horizontally. Here, being placed horizontally means that the external connecting structure is placed parallel to the first surface. Compared to the external connecting structure 105 being inclined relative to the first surface, the horizontal placement of the external connecting structure 105 is beneficial to maintaining the stability of the external connecting structure 105 on one hand, and on the other hand, enables the space occupied by the external connecting structure 105 to be relatively small, such that more space can be provided for the arrangement of other components on the surface of the main board 101, which is beneficial to the arrangement of traces.

In some embodiments, the height of the central processing unit connector relative to the main board 101 is the same as the height of the compression attached memory module 103 relative to the main board 101. In other words, the height of the surface of the central processing unit connector 106 distal to the main board 101 relative to the first surface is the same as the height of the surface of the compression attached memory module 103 opposite to the main board 101 relative to the first surface. In this way, the two ends of the external connecting structure 105 electrically connecting the central processing unit connector 106 and the compression attached memory module 103 are close in height relative to the first surface, such that the height difference between the two ends of the external connecting structure 105 is relatively small, or even 0. In this way, the external connecting structure 105 can be arranged substantially parallel to the first surface, such that the space occupied by the external connecting structure 105 on one side of the first surface is relatively small.

In some embodiments, the height of the central processing unit connector 106 relative to the main board 101 being the same as the height of the compression attached memory module 103 relative to the main board 101 may also be that: the height of the surface of the central processing unit connector 106 distal to the main board 101 relative to the first surface is the same as the height of the surface of the compression attached memory module 103 facing the main board 101 relative to the first surface.

In some embodiments, the height of the surface of the central processing unit connector 106 distal to the main board 101 relative to the first surface may be different from the height of the surface of the compression attached memory module 103 distal to the main board 101 relative to the first surface. For example, the height of the surface of the central processing unit connector 106 distal to the main board 101 relative to the first surface may be slightly higher than the height of the surface of the compression attached memory module 103 distal to the main board 101 relative to the first surface. Alternatively, the height of the surface of the central processing unit connector 106 distal to the main board 101 relative to the first surface may be slightly lower than the height of the surface of the compression attached memory module 103 distal to the main board 101 relative to the first surface.

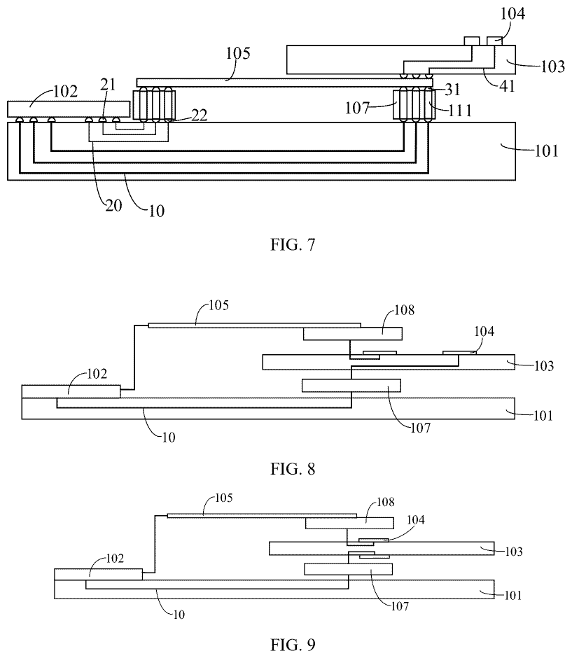

Referring to FIG. 7, in some embodiments, the main board 101 is configured to: electrically connect the central processing unit connector 106 and the central processing unit 102, where the central processing unit 102 and the main board 101 are electrically connected through a gold finger or a ball grid array; the central processing unit connector 106 and the external connecting structure 105 are electrically connected through any one of a ball grid array, a press-type connector, or a silicon interposer.

In some embodiments, the first surface is provided with a gold finger or a ball grid array, and the first surface is further provided with a first pin 21, the first pin 21 being configured to electrically connect the central processing unit 102 and the main board 101. The main board 101 is further provided with a first wire 20, the first wire 20 being configured to lead the signals of the first pin 21 to the gold finger or the ball grid array on the first surface. Further, the signals are led to the central processing unit connector 106 through the gold finger or the ball grid array. In a specific example, the material of the first wire 20 may be a metal material, such as at least one of copper, tungsten, nickel, silver, or other conductive materials well known to those skilled in the art.

In some embodiments, the surface of the central processing unit connector 106 is provided with any one of a ball grid array, a press-type connector, or a silicon interposer. A connecting structure is provided inside the central processing unit 102, and the connecting structure is configured to transmit the signals of the central processing unit 102 to the ball grid array or the press-type connector located on the surface of the central processing unit connector 106. Then, the signals are transmitted to the external connecting structure 105 via the ball grid array or the press-type connector.

In some embodiments, the surface of the central processing unit connector 106 is provided with a silicon interposer, the silicon interposer including a through silicon via. The through silicon via penetrates through the silicon interposer in the thickness direction of the silicon interposer, the bottom end of the through silicon via is in electrical contact with the connecting structure in the central processing unit connector 106, and the top end of the through silicon via is electrically connected to the external connecting structure 105.

In some embodiments, the connecting structure may be a second wire, and the embodiments of the present disclosure do not limit the specific wiring method and shape of the second wire in the central processing unit connector 106, as long as the second wire can lead the signals from the central processing unit 102 to any one of the ball grid array, the press-type connector, or the silicon interposer located on the surface of the central processing unit connector 106. The material of the second wire may be at least one of copper, tungsten, nickel, silver, or other conductive materials well known to those skilled in the art.

Referring to FIGS. 6 and 7, in some embodiments, the information processing apparatus further includes: a first adapter 107, located between the main board 101 and the compression attached memory module 103, and configured to electrically connect the main board 101 and the compression attached memory module 103. The first adapter 107 is further configured to electrically connect the external connecting structure 105 and the compression attached memory module 103. That is, the external connecting structure 105 and the main board 101 share the same first adapter 107. In this way, space can be saved.

In some embodiments, the external connecting structure 105 and the main board 101 share the same first adapter 107, the main board 101 is provided with a plurality of signal lines 10, and each signal line 10 electrically connects the central processing unit 102 and the compression attached memory module 103. The signal line 10 in the main board 101 is electrically connected to the first adapter 107, the external connecting structure 105 is electrically connected to the first adapter 107, and both the signal line 10 and the external connecting structure 105 can achieve the signal transmission between the central processing unit 102 and the chip 104.

With continued reference to FIGS. 6 and 7, in some embodiments, the external connecting structure is in electrical contact with the surface of the first adapter 107 on one side facing the compression attached memory module 103. In a specific example, the signal line 10 is electrically connected to the surface of the first adapter 107 facing the main board 101, and the external connecting structure 105 is electrically connected to the surface of the first adapter 107 on one side facing the compression attached memory module 103. That is, the external connecting structure 105 and the signal line 10 are located on two opposite surfaces of the first adapter 107, respectively, thereby avoiding the signal crosstalk between the external connecting structure 105 and the signal line 10 due to the external connecting structure 105 and the signal line 10 being located on the same surface of the first adapter 107.

One side of the first adapter 107 facing the compression attached memory module 103 is also electrically connected to the compression attached memory module 103, such that the signals transmitted in the external connecting structure 105 and the signal line 10 can be transmitted to the compression attached memory module 103.

In some embodiments, the compression attached memory module 103 is provided with: a first trace 41, the first trace 41 being configured to electrically connect a first connecting line and the chip 104, and the first trace 41 being further configured to electrically connect the first adapter 107, that is, one side of the first adapter 107 facing the compression attached memory module 103 is electrically connected to the first trace 41. The first trace 41 is configured to transmit the transmission signals from the first adapter 107 and transmit the transmission signals to the chip 104, or the signals in the chip 104 may be transmitted to the first adapter 107 through the first trace 41.

In some embodiments, the first adapter 107 may be any one of a silicon interposer or a z-axis compression connector. In some embodiments, the external connecting structure 105 may be a flexible circuit board.

In some embodiments, the first adapter 107 is a first silicon interposer, and the first silicon interposer includes a first through silicon via 111. The first through silicon via 111 penetrates through the first silicon interposer in the thickness direction of the first silicon interposer, the first silicon interposer exposes the top end and the bottom end of the first through silicon via 111, the signal line 10 is electrically connected to the bottom end of the first through silicon via 111 facing the main board 101, and the top end of the first through silicon via 111 distal to the main board 101 is electrically connected to the first trace 41.

In some embodiments, the surface of the first silicon interposer distal to the main board may further include: third pins 31, the third pins 31 being in electrical contact with the top end of the first through silicon via 111. One side of the external connecting structure 105 facing the first silicon interposer is electrically connected to the third pins 31. Since the third pins 31 are in electrical contact with the top end of the first through silicon via 111, and the bottom end of the first through silicon via 111 is electrically connected to the signal line 10, the external connecting structure 105 can also be electrically connected to the signal line. In this way, the signals transmitted in the signal line can also be transmitted to the compression attached memory module 103 through the external connecting structure 105. The remaining portion of the third pins 31 are in electrical contact with the compression attached memory module 103, and are configured to input the signals transmitted in signal lines in the main board to the compression attached memory module 103.

In some embodiments, the third pin 31 may be any one of a gold finger or a ball grid array, the electrical connecting structure may be a conductive metal wire, and the material of the electrical connecting structure may be at least one of copper, tungsten, nickel, silver, or other conductive materials well known to those skilled in the art.

A flexible circuit board is a highly reliable and highly flexible printed circuit board made of polyimide or polyester film as the substrate, and features high wiring density, light weight, thin thickness, and good bendability. Using the flexible circuit board as the external connecting structure 105 can prevent the failure of the external connecting structure 105 caused by the bending of the external connecting structure 105 during the packaging step. In addition, the flexible circuit board is relatively thin, which prevents the external connecting structure 105 from occupying excessive space, such that the overall thickness of the information processing apparatus is relatively small. This helps achieve miniaturization of the device, and helps enhance the overall heat dissipation capability of the information processing apparatus.

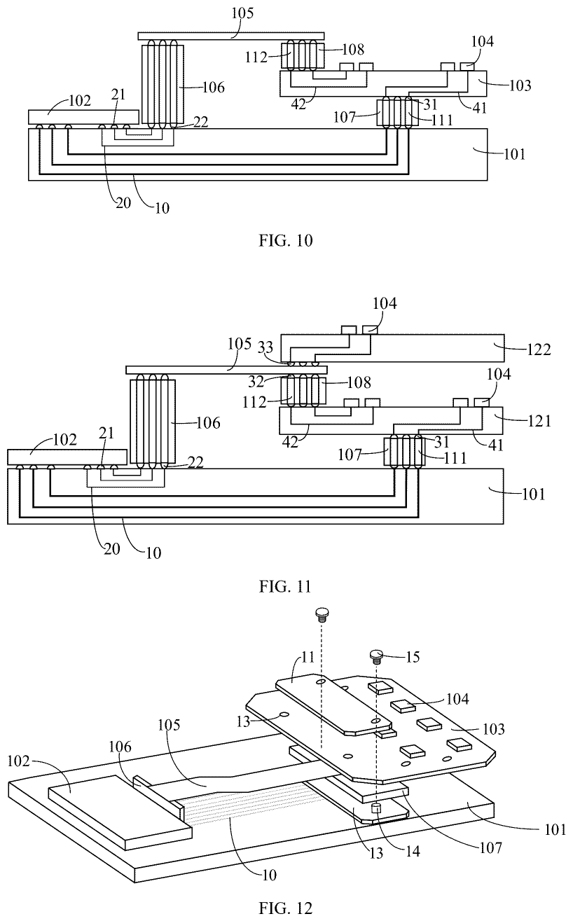

Referring to FIGS. 8 to 10, in some embodiments, the main board 101 and the external connecting structure 105 may not share the same first adapter 107, and the information processing apparatus includes: a first adapter 107, located between the main board 101 and the compression attached memory module 103, and configured to electrically connect the main board 101 and the compression attached memory module 103; and a second adapter 108, located on one side of the compression attached memory module 103 distal to the main board 101, the second adapter 108 electrically connecting the external connecting structure 105 and the compression attached memory module 103.

That is, the first adapter 107 and the second adapter 108 are located on two opposite sides of the compression attached memory module 103, respectively, the first adapter 107 is only electrically connected to the signal line 10, and the second adapter 108 is only electrically connected to the external connecting structure 105. As a result, the trace density of the traces for signal transmission in both the first adapter 107 and the second adapter 108 is relatively low, which can prevent the problem of signal crosstalk caused by excessively high trace density in the first adapter 107 and the second adapter 108.

In some embodiments, the signal line 10 in the main board 101 is electrically connected to one side of the first adapter 107 facing the main board 101, and one side of the first adapter 107 distal to the main board 101 is electrically connected to the compression attached memory module 103. The external connecting structure 105 is electrically connected to one side of the second adapter 108 distal to the compression attached memory module 103, and one side of the second adapter 108 facing the compression attached memory module 103 is electrically connected to the compression attached memory module 103.

That is, in the first adapter 107, one side with a smaller distance from the compression attached memory module 103 is electrically connected to the compression attached memory module 103, and in the second adapter 108, one side with a smaller distance from the compression attached memory module 103 is electrically connected to the compression attached memory module 103. In this way, the trace distance between the first adapter 107 and the compression attached memory module 103 can be reduced, and the trace distance between the second adapter 108 and the compression attached memory module 103 can be reduced, which is beneficial to saving the trace length.

In some embodiments, the first adapter 107 is a first silicon interposer, and the first silicon interposer includes a first through silicon via 111. The first through silicon via 111 penetrates through the first silicon interposer in the thickness direction of the first silicon interposer, the first silicon interposer exposes the top end and the bottom end of the first through silicon via 111, the signal line 10 is electrically connected to the bottom end of the first through silicon via 111 facing the main board 101, and the top end of the first through silicon via 111 distal to the main board 101 is electrically connected to the compression attached memory module 103. The second adapter 108 is a second silicon interposer, and the second silicon interposer includes a second through silicon via 112. The second through silicon via 112 penetrates through the second silicon interposer in the thickness direction of the second silicon interposer, and the second silicon interposer exposes the top end and the bottom end of the second through silicon via 112. The bottom end of the second through silicon via 112 is directly opposite to the surface of the compression attached memory module 103 distal to the main board 101, and is electrically connected to one side of the compression attached memory module 103 distal to the main board 101. The external connecting structure 105 is electrically connected to the top end of the second through silicon via 112.

In some embodiments, the information processing apparatus includes a first adapter 107 and a second adapter 108, and the compression attached memory module 103 is provided with: a first trace 41, the first trace 41 being configured to electrically connect a first connecting line and the chip 104, and the first trace 41 being further configured to electrically connect the first adapter 107; and a second trace 42, the second trace 42 being configured to electrically connect the external connecting structure 105 and the chip 104, and the second trace 42 being further configured to electrically connect the second adapter 108.

In some embodiments, the compression attached memory module 103 includes a third surface and a fourth surface that are opposite to each other, the fourth surface is directly opposite to the first surface, and the first trace 41 and the second trace 42 are spaced apart in the direction parallel to the third surface. That is, the second trace 42 and the first trace 41 are horizontally arranged. In this way, the second trace 42 and the first trace 41 do not occupy the space in the thickness direction of the compression attached memory module 103. Compared to the second trace 42 and the first trace 41 being spaced apart in the thickness direction of the compression attached memory module 103, the second trace 42 and the first trace 41 being spaced apart in the direction parallel to the third surface significantly reduces the thickness of the compression attached memory module 103.

In some embodiments, the top end of the first through silicon via 111 is electrically connected to the first trace 41, and the bottom end of the second through silicon via 112 is electrically connected to the second trace 42, where the top end of the first through silicon via 111 is directly opposite to the third surface, and the bottom end of the second through silicon via 112 is directly opposite to the fourth surface.

Referring to FIG. 8, in some embodiments, one of the surfaces of the compression attached memory module in the direction perpendicular to the first surface is provided with a plurality of chips 104. In some embodiments, the compression attached memory module 103 includes a third surface and a fourth surface that are opposite to each other, and the third surface is directly opposite to the first surface. The plurality of chips 104 may be located only on the third surface or only on the fourth surface. Each chip 104 may be electrically connected to any one of the external connecting structure 105 or the signal line 10. That is, the central processing unit 102 may read data from or write data to the chip 104 through any one of the external connecting structure 105 or the signal line 10.

Referring to FIG. 9, in some embodiments, two opposite surfaces of the compression attached memory module 103 in the direction perpendicular to the first surface are both provided with the plurality of chips 104. That is, both the third surface and the fourth surface are provided with a plurality of chips 104. In this way, the integration level of the chips 104 can be improved.

Referring to FIG. 9, in some embodiments, the information processing apparatus includes: a first adapter 107 and a second adapter 108, where the first adapter 107 is located on one side of the third surface, the second adapter 108 is located on one side of the fourth surface, the external connecting structure 105 is electrically connected to the second adapter 108, and the signal line 10 is electrically connected to the first adapter 107. The second adapter 108 may be electrically connected to the chip 104 on the fourth surface, that is, the central processing unit 102 reads data from and writes data to the chip 104 located on the fourth surface through the external connecting structure 105. The first adapter 107 may be electrically connected to the chip 104 on the third surface, and the central processing unit 102 may read data from and write data to the chip 104 located on the third surface through the signal line 10 in the main board 101. In this way, the trace length can be saved, and the traces are simplified.

Referring to FIG. 8, in some embodiments, each chip 104 of the plurality of chips 104 located on the third surface may also be electrically connected to any one of the external connecting structure 105 or the signal line 10. Each chip 104 of the plurality of chips 104 located on the fourth surface may also be electrically connected to any one of the external connecting structure 105 or the signal line 10.

Referring to FIG. 11, in some embodiments, two compression attached memory modules are provided, the two compression attached memory modules 103 are stacked in the direction perpendicular to the first surface, and the two compression attached memory modules 103 are electrically connected to the central processing unit 102 through the same external connecting structure 105. At least one surface of each compression attached memory module 103 of the two compression attached memory modules 103 is provided with a plurality of chips 104. Through the same external connecting structure 105, the central processing unit 102 can read data from and write data to the chips 104 located on the surface of any compression attached memory module 103, thereby increasing the number of chips 104 electrically connected to the central processing unit 102 without increasing the number of external connecting structures 105, and further improving the integration level of the chips 104.

Since the external connecting structure 105 is arranged outside the main board 101, the number of the signal lines 10 in the main board 101 can be reduced, and even the arrangement of the signal lines 10 in the main board 101 can be eliminated. In this way, the heat dissipation capability of the main board 101 can be enhanced while the integration level of the chips 104 is improved, which is beneficial to ensuring the excellent performance of the main board 101 and ensuring that the information processing apparatus has a high operating speed.

In some embodiments, the two compression attached memory modules 103 are respectively denoted as: a first compression attached memory module 121 and a second compression attached memory module 122. The first compression attached memory module 121 is adjacent to the first surface, and the second compression attached memory module 122 is located on one side of the first compression attached memory module 121 distal to the main board 101.

The information processing apparatus may include: a first adapter 107 and a second adapter 108. The first adapter 107 is located between the first compression attached memory module 121 and the first surface, and is configured to electrically connect the main board 101 and the first compression attached memory module 121. The second adapter 108 is located between the first compression attached memory module 121 and the second compression attached memory module 122, and is configured to electrically connect the external connecting structure 105. In addition, the second adapter 108 is electrically connected to the first compression attached memory module 121 and the second compression attached memory module 122, and is configured to transmit signals in the external connecting structure 105 to the first compression attached memory module 121 and the second compression attached memory module 122 separately.

In a specific example, the first adapter 107 may be a first silicon interposer, and the second adapter 108 may be a second silicon interposer. The first silicon interposer includes a first through silicon via 111, the first through silicon via 111 penetrating through the first silicon interposer. The top end of the first through silicon via 111 is electrically connected to the first compression attached memory module 121, and the bottom end of the first through silicon via 111 is electrically connected to the main board 101. Specifically, the main board 101 may be provided with signal lines 10, the signal lines 10 are electrically connected to the central processing unit 102, and the bottom end of the first through silicon via 111 may be electrically connected to the signal lines 10.

The second silicon interposer includes a second through silicon via 112, the second through silicon via 112 penetrating through the second silicon interposer. The top end of the second through silicon via 112 is electrically connected to the second compression attached memory module 122, and the bottom end of the second through silicon via 112 is electrically connected to the first compression attached memory module 121.

In some embodiments, the surface of the second silicon interposer may include: fourth pins 32, the fourth pins 32 being located on any one of the surface of the second silicon interposer distal to the main board 101 or the surface of the second silicon interposer facing the main board 101. The surface of the external connecting structure 105 facing the second silicon interposer is in electrical contact with the third pins 31, such that the signals transmitted in the external connecting structure 105 can be transmitted to the second through silicon via 112 through the third pins 31, and finally transmitted to the first compression attached memory module 121 through the second through silicon via 112.

The surface of the second compression attached memory module 122 facing the second silicon interposer may include: fifth pins 33. The fifth pins 33 are in electrical contact with the surface of the external connecting structure facing the second compression attached memory module 122, such that the signals transmitted in the external connecting structure 105 can be transmitted to the second compression attached memory module 122 through the fifth pins 33.

In some embodiments, the fourth pin 32 may be any one of a gold finger or a ball grid array, the electrical connecting structure may be a conductive metal wire, and the material of the electrical connecting structure may be at least one of copper, tungsten, nickel, silver, or other conductive materials well known to those skilled in the art. In some embodiments, the fifth pin 33 may be any one of a gold finger or a ball grid array, the electrical connecting structure may be a conductive metal wire, and the material of the electrical connecting structure may be at least one of copper, tungsten, nickel, silver, or other conductive materials well known to those skilled in the art.

Referring to FIG. 12, in some embodiments, the information processing apparatus further includes: a top pad 11, located on the surface of the compression attached memory module 103 distal to the main board 101, where the top pad 11 is provided with at least one mounting hole 13; a bottom pad 12, fixed to the first surface, where the bottom pad 12 is located on the surface of the compression attached memory module 103 facing the main board 101, and the bottom pad 12 is provided with at least one latch 14 corresponding to the mounting hole 13; and a fastener 15, matched with the latch 14, where the fastener 15 is configured to fix the latch 14 after the latch 14 passes through the mounting hole 13, such that the top pad 11 and the bottom pad 12 clamp and fix the compression attached memory module 103.

In some embodiments, the top pad 11 may be provided with two mounting holes 13, and the bottom pad 12 may also be provided with two latches 14, each latch 14 corresponding to one mounting hole 13. The two mounting holes 13 are located on two opposite sides of the top pad 11, respectively. In this way, the mounting stability of the top pad and the bottom pad 12 can be improved.

In some embodiments, the top pad 11 may also be provided with more than two mounting holes 13, and the bottom pad 12 may also be provided with more than two latches 14; or the top pad 11 may also be provided with only one mounting hole 13, and the bottom pad 12 may also be provided with only one latch 14. The requirement is that the number of the mounting holes 13 matches the number of the latches 14. The number of the mounting holes 13 and the number of the latches 14 can be flexibly set according to different requirements.

In some embodiments, the latch 14 may be a screw thread insert. The screw thread insert is an internally threaded fastener 15, and the inner side of the screw thread insert is provided with internal threads. The fastener 15 may be any one of screws. The screw can be locked with the screw thread insert by being screwed into the screw thread insert, such that after the screw thread insert is inserted into the mounting hole 13, the screw thread insert is fixed in the mounting hole 13 to prevent the screw thread insert from slipping out of the mounting hole 13.

In some embodiments, the latch 14 may also be a bolt, and the fastener 15 may also be a nut. The side surface of the bolt is provided with external threads, and the interior of the nut is provided with internal threads matching the external threads on the outer side of the bolt. After the bolt is inserted into the mounting hole 13, the nut is screwed onto the outer side surface of the bolt to be locked with the bolt, and then the bolt is fixed in the mounting hole 13 to prevent the bolt from slipping out of the mounting hole 13, such that the top pad and the bottom pad 12 can clamp and fix the compression attached memory module 103 to prevent the compression attached memory module 103 from moving.

In the information processing apparatus provided in the foregoing embodiments, the external connecting structure 105 is arranged on one side of the first surface of the main board 101, and is configured to electrically connect the compression attached memory module 103 and the central processing unit 102. That is, the external connecting structure 105 is routed from the outside of the main board 101 to connect the compression attached memory module 103 and the central processing unit 102. In this way, the number of the signal lines 10 in the main board 101 configured to electrically connect the central processing unit 102 and the compression attached memory module 103 can be reduced, and even the arrangement of the signal lines 10 in the main board 101 can be eliminated, thereby significantly reducing the thickness of the main board 101, significantly reducing the heat dissipation path of the main board 101, and facilitating the enhancement of the heat dissipation of the main board 101.

Those of ordinary skill in the art can understand that the foregoing implementations are specific embodiments of practicing the present disclosure, while in practical application, various changes can be made to the implementations in form and detail without departing from the spirit and scope of the present disclosure. Any person skilled in the art can make various changes and modifications without departing from the spirit and scope of the present disclosure, and the protection scope of the present disclosure shall be defined by the appended claims.

What is claimed is:

1. An information processing apparatus, comprising:
a main board, provided with a first surface, wherein the first surface is provided with a central processing unit electrically connected to the main board;
a compression attached memory module, located on one side of the first surface, wherein at least one surface of the compression attached memory module is provided with a plurality of chips; and
an external connecting structure, located on one side of the first surface, and configured to: electrically connect the compression attached memory module and the central processing unit, wherein the central processing unit is configured to: read data from and write data to each of the plurality of chips at least via the external connecting structure.

2. The information processing apparatus according to claim 1, wherein the main board is provided with a plurality of signal lines, each of the plurality of signal lines electrically connects the central processing unit and the compression attached memory module, and the central processing unit is configured to: read data from and write data to each chip via the signal line and the external connecting structure.

3. The information processing apparatus according to claim 1, wherein the external connecting structure is located on one side of the compression attached memory module facing the central processing unit.

4. The information processing apparatus according to claim 3, wherein a height of the compression attached memory module relative to the main board is greater than a height of the central processing unit relative to the main board.

5. The information processing apparatus according to claim 1, further comprising: a central processing unit connector, wherein the central processing unit connector is located on the first surface, and a height of the central processing unit connector relative to the main board is greater than the height of the central processing unit relative to the main board.

6. The information processing apparatus according to claim 5, wherein the height of the central processing unit connector relative to the main board is the same as the height of the compression attached memory module relative to the main board.

7. The information processing apparatus according to claim 5, wherein a bottom surface of the central processing unit connector facing the first surface is electrically connected to the central processing unit, and a top surface of the central processing unit connector distal to the first surface is electrically connected to the external connecting structure.

8. The information processing apparatus according to claim 6, wherein the main board is configured to: electrically connect the central processing unit connector and the central processing unit, wherein the central processing unit and the main board are electrically connected through a gold finger or a ball grid array; and the central processing unit connector and the external connecting structure are electrically connected through any one of a ball grid array, a press-type connector, or a silicon interposer.

9. The information processing apparatus according to claim 1, further comprising: a first adapter, located between the main board and the compression attached memory module, and configured to electrically connect the main board and the compression attached memory module, wherein the first adapter is further configured to electrically connect the external connecting structure and the compression attached memory module.

10. The information processing apparatus according to claim 9, wherein the external connecting structure is in electrical contact with a surface of the first adapter on one side facing the compression attached memory module.

11. The information processing apparatus according to claim 1, further comprising:
a first adapter, located between the main board and the compression attached memory module, and configured to electrically connect the main board and the compression attached memory module; and
a second adapter, located on one side of the compression attached memory module distal to the main board, wherein the second adapter electrically connects the external connecting structure and the compression attached memory module.

12. The information processing apparatus according to claim 11, wherein two compression attached memory modules are provided, the two compression attached memory modules are stacked in a direction perpendicular to the first surface, and the two compression attached memory modules are electrically connected to the central processing unit through the same external connecting structure.

13. The information processing apparatus according to claim 9, wherein the first adapter is any one of a silicon interposer or a z-axis compression connector; and the external connecting structure is a flexible circuit board.

14. The information processing apparatus according to claim 1, wherein one of surfaces of the compression attached memory module in a direction perpendicular to the first surface is provided with the plurality of chips; or two opposite surfaces of the compression attached memory module in the direction perpendicular to the first surface are both provided with the plurality of chips.

15. The information processing apparatus according to claim 1, further comprising:
a top pad, located on a surface of the compression attached memory module distal to the main board, wherein the top pad is provided with at least one mounting hole;
a bottom pad, fixed to the first surface, wherein the bottom pad is located on a surface of the compression attached memory module facing the main board, and the bottom pad is provided with at least one latch corresponding to the at least one mounting hole; and
a fastener, matched with the latch, wherein the fastener is configured to fix the latch after the latch passes through the at least one mounting hole, such that the top pad and the bottom pad clamp and fix the compression attached memory module.
